(19) United States
(12) Patent Application Publication
(10) Pub. No.: US 2013/0056774 A1
(43) Pub. Date: Mar. 7, 2013

(54) LENS, PACKAGE AND PACKAGING METHOD FOR SEMICONDUCTOR LIGHT-EMITTING DEVICE

(71) Applicants: Jhih-Sin HONG, Taichung City (TW); Shih-Feng SHAO, New Taipei City (TW)

(72) Inventors: Jhih-Sin HONG, Taichung City (TW); Shih-Feng SHAO, New Taipei City (TW)

(73) Assignee: PHOSTEK, INC., Taipei City (TW)

(21) Appl. No.: 13/311,739

(22) Filed: Dec. 6, 2011

Related U.S. Application Data
(60) Provisional application No. 61/530,747, filed on Sep. 2, 2011.

(51) Int. Cl. H01L 33/58; F21V 5/04; H01L 33/52

(52) U.S. Cl. 257/98; 438/27; 362/235; 257/E33.068; 257/E33.059

(57) ABSTRACT

This invention provides lenses having a pendant shape profile and their applications and forming methods. In an embodiment, the lenses are used to encapsulate one or more light-emitting diode chips so as to increase the light extraction efficiency.

### BACKGROUND OF THE INVENTION

1. Field of the Invention

This invention generally relates to lenses for semiconductor light-emitting devices, and more particularly relates to lenses having a pendant shape profile and their applications and forming methods.

2. Description of Related Art

Various types of light-emitting diodes (LEDs) have been developed and are increasingly used nowadays. A packaging process is made after light-emitting diode chips are fabricated. The package provides essential supports, including mechanical, electrical, thermal, and optical supports, to the light-emitting diode chips.

Typically a package employs a lens or a case made of epoxy resins, silicone, or other materials to cover or encapsulate one or several LED chips. The lens can prevent the LED chips from being damaged by the moisture or chemicals. The lens doped with phosphors can alter the emitting color. With better package design, the lens can even increase the emitting efficiency.

FIG. 1A to FIG. 1C illustrate a conventional packaging method. FIG. 1A shows a light-emitting diode chip 10 is mounted on a leadframe 12. FIG. 1B shows a mold 14 with an injection hole 14a and an air vent 14b. The mold 14 is then placed on the leadframe 12 and an epoxy resin or a silicone is injected into the mold 14 via the injection hole 14a until the mold 14 is filled with the resin. The resin is then cured and bound to the mold (or the mold may be removed), so as to obtain a light-emitting diode package with a semicircle-shaped lens, as shown in FIG. 1C.

The mold 14 is costly. Some manufacturers develop a dispensing method to lower the cost. FIG. 2 illustrates a conventional light-emitting diode package formed by the dispensing method. Instead of using the mold, this method features in that the epoxy resin or silicone is directly dispensed on the LED chip. After curing, the dispensed material forms a lens 20 to encapsulate the LED chip.

Typically, the lens 20 formed by the dispensing method is less round than the lens 16 formed by the molding method, and experimental results show that for a same packaged LED chip, the latter can enhance more emitting power of the chip than the former. Although the dispensing method has an advantage of low cost, the emitting efficiency by this method is reduced.

It would be advantageous to provide novel packages or packaging methods for enhancing the emitting power of light-emitting devices in a cheap manner.

### SUMMARY OF THE INVENTION

An object of this invention is to provide novel packages or packaging methods for enhancing the emitting power of light-emitting devices.

An embodiment of this invention provides a packaging method for semiconductor light-emitting devices, comprising the steps of: dispensing a sealing material to encapsulate one or more semiconductor light-emitting devices disposed on a supporting mechanism; reversing the supporting mechanism; and curing the sealing material.

Another embodiment of this invention provides a package formed by the foregoing packaging method.

Another embodiment of this invention provides a lens with a pendant shape profile used to encapsulate one or more semiconductor light-emitting devices and enhance the output power of the one or more semiconductor light-emitting devices.

Another embodiment of this invention provides a light-emitting device package, comprising: a supporting mechanism for supporting one or more semiconductor light-emitting devices; and a lens with a pendant shape profile covering the one or more semiconductor light-emitting devices.

### BRIEF DESCRIPTION OF THE DRAWINGS

FIG. 1A to FIG. 1C illustrate a conventional packaging method.

FIG. 2 illustrates a package formed by the conventional dispensing method.

FIG. 3 shows a lens and a package according to a preferred embodiment of this invention.

FIG. 4A to FIG. 4F show a packaging method according to an embodiment.

FIG. 5A to FIG. 5G show another packaging method according to an embodiment.

FIG. 6 shows the temperature-versus-storage modulus curves of some sealing materials.

FIG. 7 is a histogram showing the emitting power of the packaged LED chips formed by the method of this invention and conventional dispensing method.

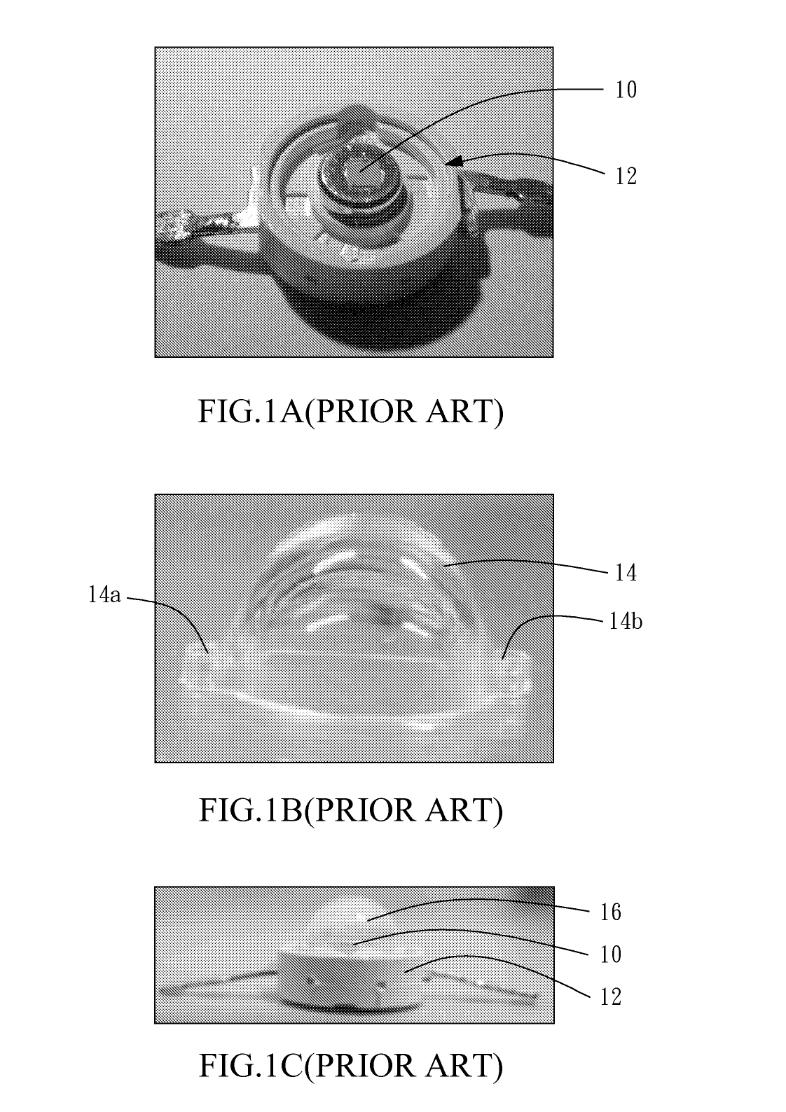

### DESCRIPTION OF THE PREFERRED EMBODIMENT

Reference will now be made in detail to specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known components and process operations have not been described in detail in order not to unnecessarily obscure the present invention. While drawings are illustrated in detail, it is appreciated that the quantity of the disclosed components may be greater or less than that disclosed, except where expressly restricting the amount of the components.

FIG. 3 shows a lens 32 and a package 30 according to a preferred embodiment of this invention. The lens 32 features in a pendant shape profile, and more particularly, the profile may be bell-shaped, having at least two inflection points P. In addition, the pendant shape profile is gravity-distorted, i.e., naturally formed by gravity. The package 30 employs the lens 32 to encapsulate or cover one or more semiconductor light-emitting devices 34, which may include, but are not limited to, light-emitting diodes. The lens 32 can enhance the output power of the one or more semiconductor light-emitting devices 34. In this context, “pendant shape” may comprise or refer to the shape of a drop of liquid clinging to an overlying surface and the like.

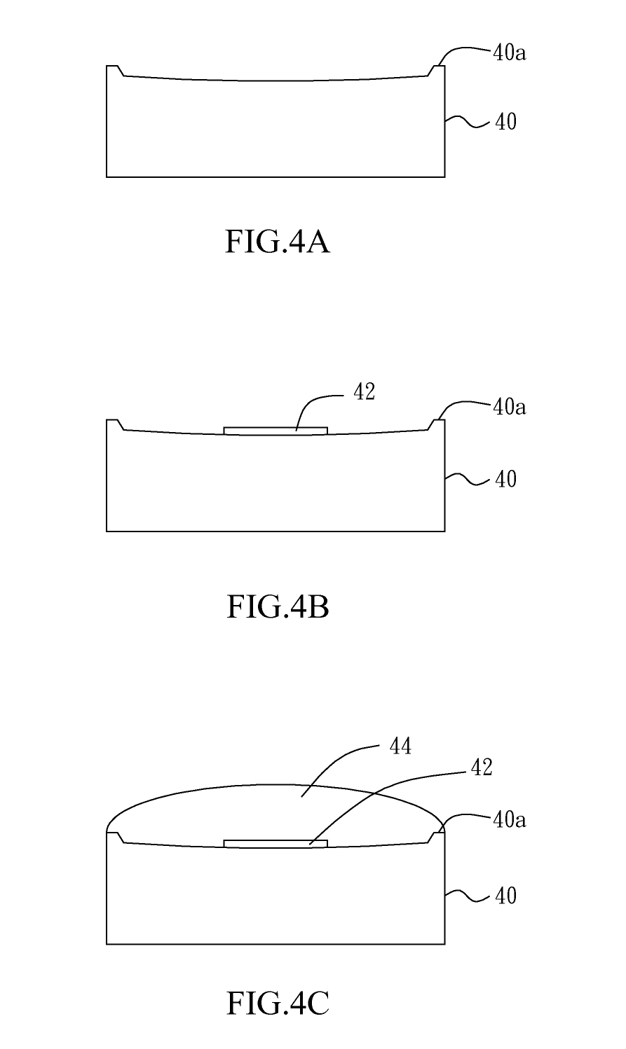

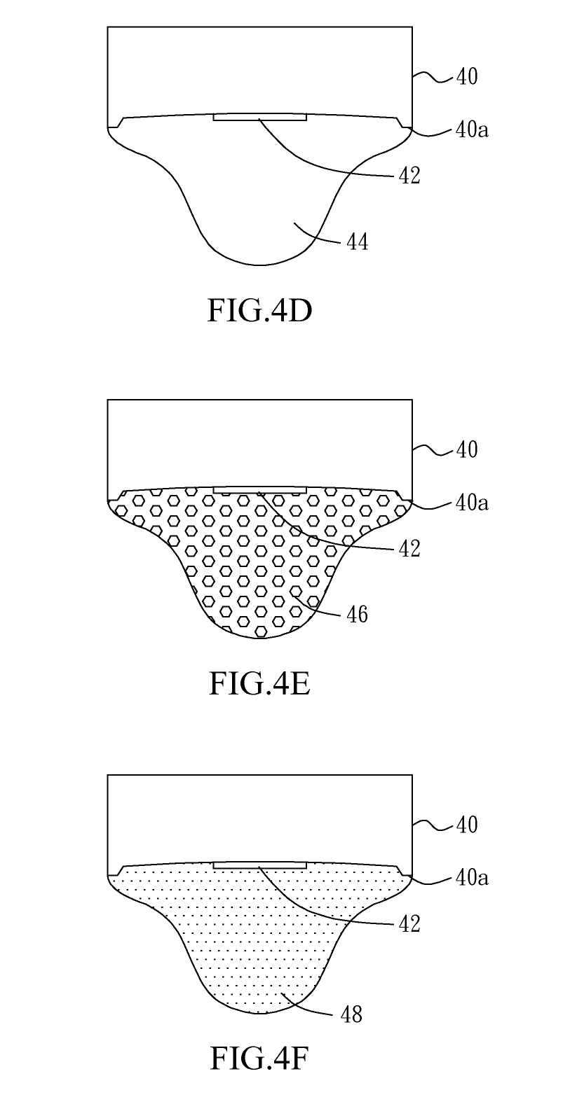

FIG. 4A to FIG. 4F show a packaging method according to an embodiment. Referring to FIG. 4A, a supporting mechanism 40 is provided. The supporting mechanism 40 may include, but is not limited to, a leadframe, a sub-mount, a board, or a substrate, such as a printed circuit board, a metal board, a composite board, or a semiconductor substrate. For illustrative purpose, the supporting mechanism 40 is a leadframe 40 in this embodiment. In some embodiments, light-emitting devices 34 may be LED chips or dies or emitters. LED chip bonding on supporting mechanism 40 may be achieved using thermosonic bonding, thermocompressive bonding, ultrasonic bonding, glue bonding, eutectic bonding with or without underfill, or so forth.

Referring to FIG. 4B, one or more semiconductor light-emitting devices 42 are mounted on the supporting mechanism 40. For illustrative purposes, the one or more semiconductor light-emitting devices 42 is a light-emitting diode (LED) chip 42 in this embodiment. The LED chip 42 may be fixed via a silver paste (not shown), for example. In addition, electrical connection may be built between the one or more semiconductor light-emitting devices 42 and the supporting mechanism 40 via various structures and methods known in the art, such as a wire bonding step.

Referring to FIG. 4C, a sealing material 44 is dispensed to encapsulate or cover the LED chip 42. The sealing material 44 may include, but is not limited to, an epoxy resin, a silicone, a UV curing resin, or other suitable materials with a suitable refractive index, so as to increase the light extraction efficiency. The sealing material 44 is typically a polymer and may also include one or more types of phosphor, dispersing particles, and heat-dissipating particles. In addition, the dispensing amount is precisely calculated through experiments. In addition, the supporting mechanism 40 may comprise an enclosed flange 40a or an enclosed groove (not shown) arranged at the periphery of the top surface of the supporting mechanism 40, for more precisely controlling the dispensing pattern. The area covered by the sealing material on the supporting mechanism is restricted by at least one enclosed groove or at least one enclosed flange.

Referring to FIG. 4D, the supporting mechanism 40 is then turned upside down. A fixture may be employed to assist the turning step. After being turned upside down, the gravity draws the sealing material 44 downward, making it with a pendant or inverted bell shape. The substantially Gaussian, axisymmetrical pendant shape is influenced by the affinity of the sealing material to the supporting mechanism and LED chip, the surface tension and viscosity of the sealing material, and the force of gravity.

Referring to FIG. 4E, the sealing material 44 is then heated with a first temperature for a first predetermined period. After heating, the sealing material 44 is in a partially hardened state 46, a tack-free state 46, or a rubber-like state 46, which will not deform by gravity.

Referring to FIG. 4F, the partially hardened or tack-free sealing material 46 is then heated with a second temperature for a second predetermined period, causing the partially hardened sealing material 46 completely harden or cross-link, thus forming a lens 48.

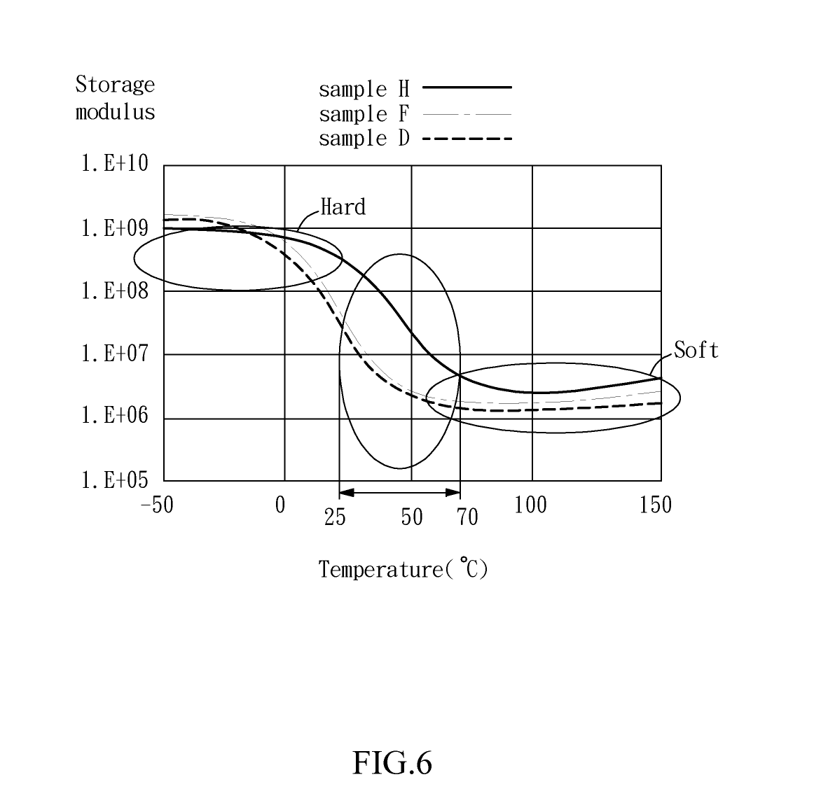

The selection of the first temperature, second temperature, and heating periods depend on the types and the compositions of the sealing material. Preferably, they can be determined by the temperature-versus-storage modulus curve of the selected sealing material. The curves typically show a minimum storage modulus corresponding to a third temperature, and a temperature a bit less than the third temperature may be used as the first temperature. FIG. 6 illustrates three characteristic curves of three different sealing materials including sample D, sample F, and sample H. Each curve can be divided into a hard section, a soft section, and an intermediate section between the two sections. As the temperature increases, the sealing materials become softer. Typically, the first temperature is at the intermediate section, and the second temperature is at the soft section. Taking sample D as an example, the first temperature and its period may range from about 25° C. to 70° C. and about 10 min to 30 min, preferably 70° C. for 20 min; and the second temperature and its period may be about 150° C. for 1 hr to 2 hr.

Notice that although this embodiment employs a two-step curing to cure or harden the pendent sealing material, a multi-step curing may be accepted in other embodiments of this invention. It is also possible that only one step is used to cure the pendent sealing material, if it can be cured or hardened in a short period. In addition, instead of raised temperature, the pendent sealing material 44 may be cured or hardened via other physical or chemical methods, such as radiation [e.g. ultraviolet (UV) light] based curing, electromagnetic wave-based curing, and so on.

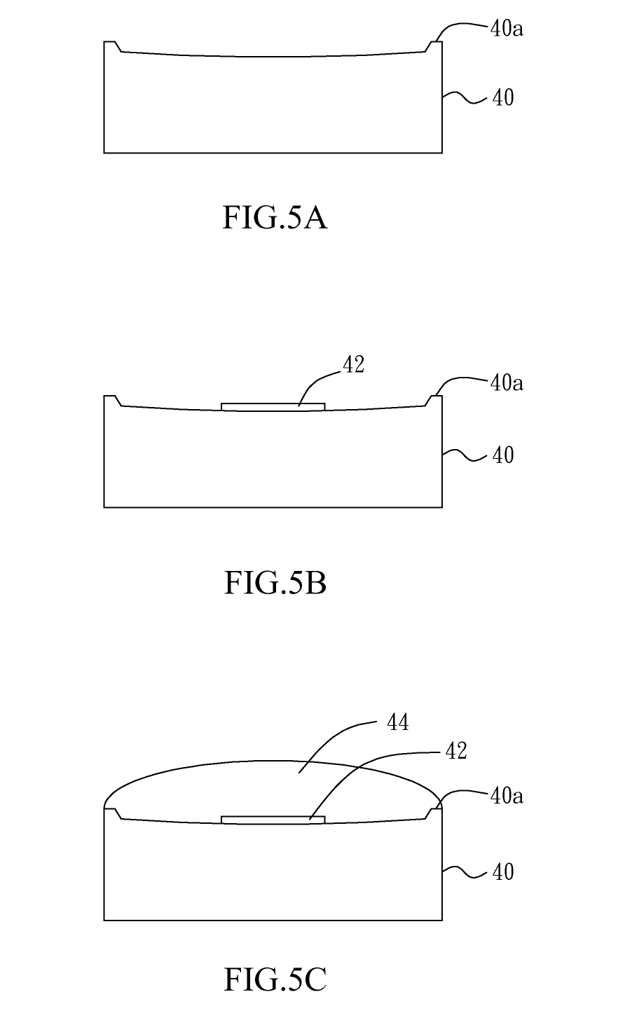

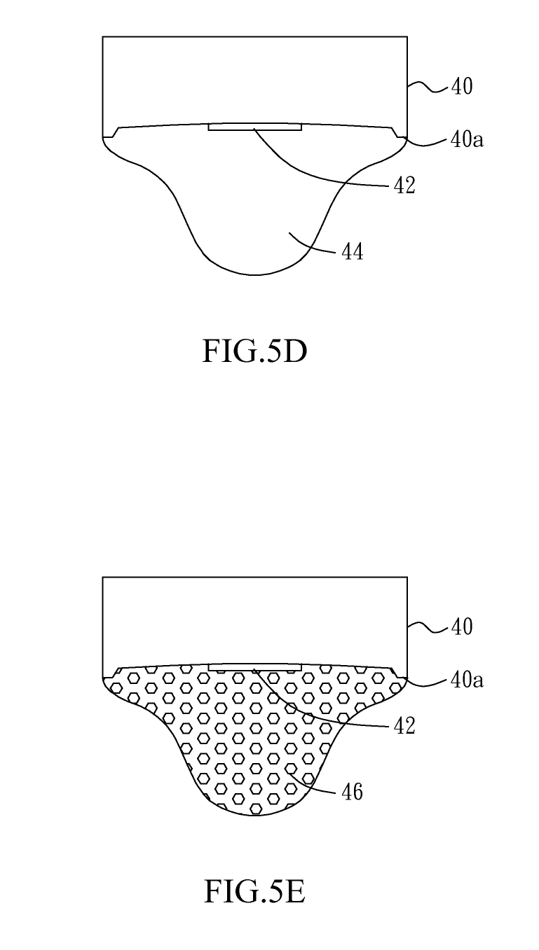

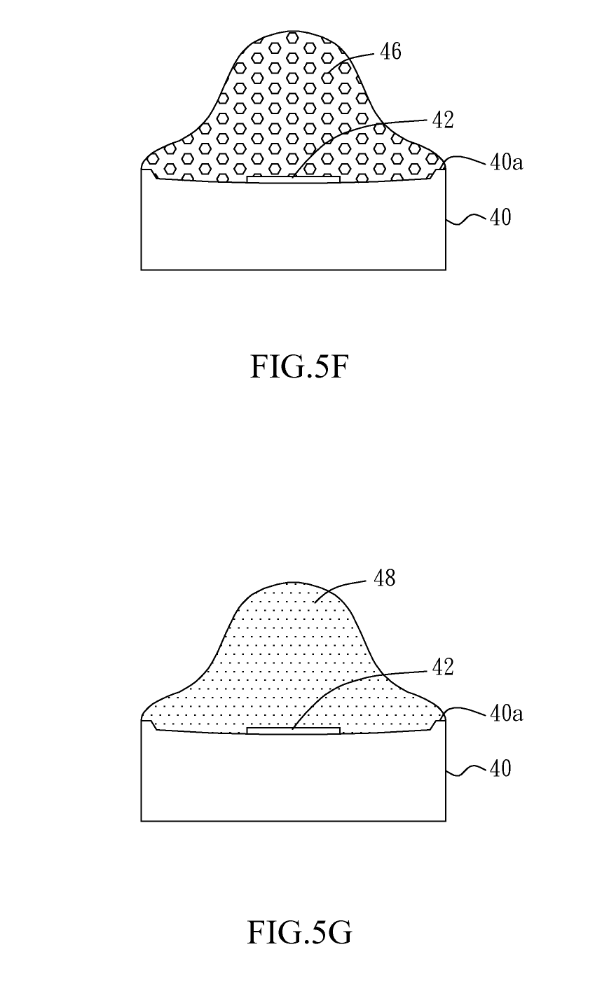

FIG. 5A to FIG. 5G show another packaging method according to another embodiment of this invention. This method is a modification of the method shown in FIG. 4A to FIG. 4F, and the difference between them is the step of FIG. 5F. Referring to FIG. 5F, after the sealing material 44 is heated to a partially hardened state 46, a tack-free state 46, or a rubber-like state 46, the supporting mechanism 40 is reversed again, making the partially hardened sealing material 46 toward upside. Referring to FIG. 5G, the partially hardened or tack-free sealing material 46 is then heated with a second temperature for a predetermined period, making it completely hardened or cross-linked, and thus forming a wanted lens 48.

Experiments are made to investigate the emitting power of packages formed by the foregoing methods. Table 1 lists the specification of some sealing materials used in the experiments. All illustrative sealing materials are two-part form and they will be mixed before using.

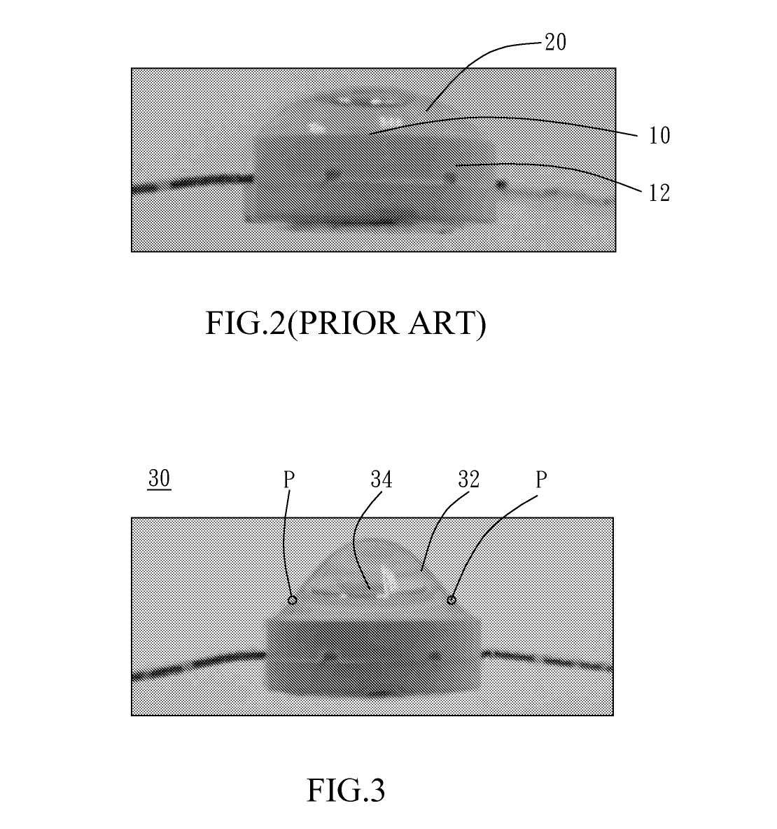

Table 2 shows experiments for finding an optimum dispensing amount of a sealing material, in which nine samples labeled with “down” employ the methods described in FIG. 4A to FIG. 4F, and eight samples labeled with “upside” employ the conventional dispensing method shown in FIG. 2. In this example, an optimum dispensing amount of “down method” is about 0.08±0.002 g.

Table 3 lists performances of the light-emitting diode chip, including data before packaging and after packaging. Comparative samples are also made for comparison. By the method of this invention, i.e., samples labeled with “down,” the output power of the light-emitting diode chip is increased by 33%-37% (equal to or more than 30%) after being encapsulated by the lens. By the conventional dispensing method, i.e., samples labeled with “upside,” the output power of the light-emitting diode chip is increased only by 15%-21% after being encapsulated by the lens.

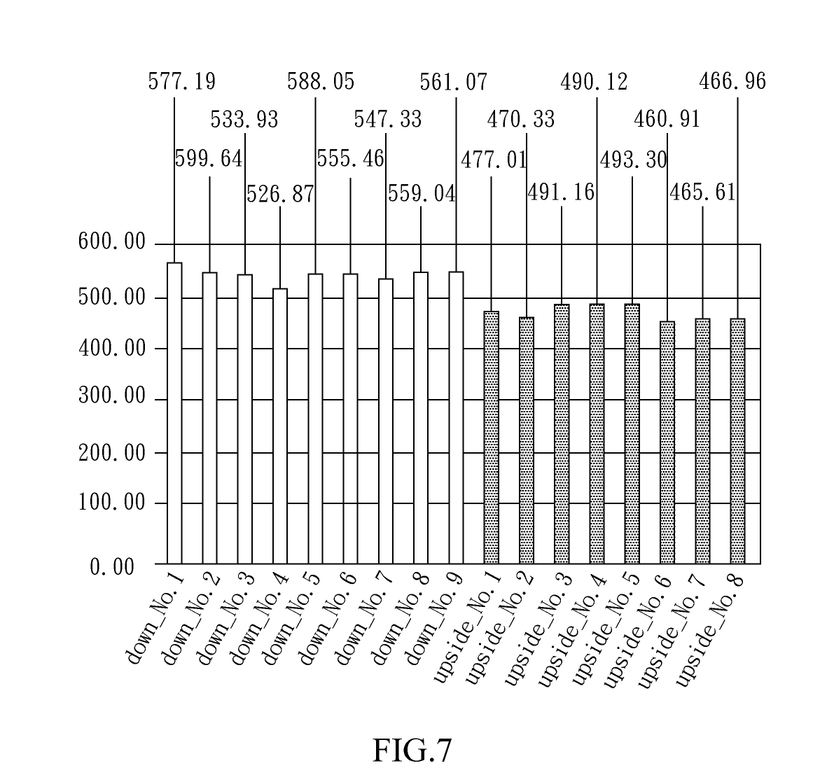

The results of Table 3 are also shown in a histogram of FIG. 7. In addition, Table 4 lists performance of comparative samples formed by the conventional molding method. The average radiant flux of the packaged LED chips is 554.5 mW by the molding method, 555.4 mW by the method of this invention, and 476.8 mW by the conventional dispensing method. The results show that, without using a mold, the package of this method can enhance the emitting power superior to the packages formed by the conventional dispensing method and comparable to those formed by the molding method.

Although specific embodiments have been illustrated and described, it will be appreciated by those skilled in the art that various modifications may be made without departing from the scope of the present invention, which is intended to be limited solely by the appended claims.

TABLE 1

| Sealing | | | | | | | | | |
|---|---|---|---|---|---|---|---|---|---|
| materials | A | B | C | D | E | F | G | H | I |
| Mix ratio | 1:1 | 1:1 | 1:1 | 1:3 | 1:2 | 1:4 | 1:2 | 1:20 | 1:1 |
| Viscosity | 2,900 | 10,000 | 22,000 | 31,700 | 13,000 | 2,100 | 5,900 | 100 | 20,000 |
| (Part A) | | | | | | | | | |
| (mPa · S) | | | | | | | | | |
| Viscosity | 1,400 | 1,000 | 1,100 | 2,850 | 5,100 | 2,300 | 13,500 | 2,400 | 7,000 |
| (Part B) | | | | | | | | | |
| (mPa · S) | | | | | | | | | |
| Viscosity | 1,800 | 2,000 | 4,000 | 5,000 | 7,650 | 2,500 | 7,150 | 2,200 | 14,000 |
| (Mixed) | | | | | | | | | |
| (mPa · S) | | | | | | | | | |
| Curing | 100° C. for | 150° C. for | 150° C. for | 150° C. for | 150° C. for | 150 C for. | 150° C. for | 150° C. for | <1 min |
| condition | 1 hr | 1 hr | 1 hr | 2 hr | 1 hr | 2 hr | 2 hr | 2 hr | @170° C. |
| Hardness | Penetration | 26 (JISA) | 62 (JISA) | 33 | 34 | 41 | 69 | 68 | 67 |
| | 70 | | | (shoreD) | (shoreD) | (shoreD) | (shoreA) | (shoreD) | (shoreD) |

TABLE 2

| | Weight of | Weight | After | |
|---|---|---|---|---|
| | leadframe, fixed | of glue | cured | |
| down | chip, and wire (g) | (g) | (g) | Note |
| 1. | 0.584 | 0.080 | 0.657 | |
| 2. | 0.582 | 0.080 | 0.663 | |
| 3. | 0.582 | 0.081 | 0.660 | |
| 4. | 0.582 | 0.080 | 0.660 | |
| 5. | 0.583 | 0.078 | 0.661 | |
| 6. | 0.583 | 0.085 | 0.675 | fail |
| 7. | 0.581 | 0.082 | 0.662 | |
| 8. | 0.582 | 0.081 | 0.663 | |
| 9. | 0.583 | 0.082 | 0.662 | |
| | Weight of | Weight | After | |
| | leadframe, fixed | of glue | cured | |
| Upside | chip, and wire | (g) | (g) | Note |
| 1. | 0.581 | 0.081 | 0.661 | |
| 2. | 0.583 | 0.082 | 0.664 | |
| 3. | 0.583 | 0.083 | 0.666 | |
| 4. | 0.582 | 0.081 | 0.662 | |
| 5. | 0.583 | 0.083 | 0.666 | |
| 6. | 0.582 | 0.086 | 0.658 | |
| 7. | 0.582 | 0.081 | 0.663 | |
| 8. | 0.582 | 0.083 | 0.645 | fail |
| | | | | (150° C.) |

TABLE 3

| | | | | Radiant | Luminous | | | | Radiant | | |
|---|---|---|---|---|---|---|---|---|---|---|---|
| | Current ^{a} | Voltage ^{a} | Watt ^{a} | Flux ^{a} | Flux ^{a} | WPE ^{a} | Voltage ^{b} | Watt ^{b} | Flux ^{b} | WPE ^{b} | Enhance |
| Scans | (A) | (V) | (W) | mW | lumen | % | (V) | (W) | mW | % | % |
| down_No. 1 | 0.350 | 3.31 | 1.16 | 434.44 | — | 0.37 | 3.32 | 1.16 | 577.19 | 0.50 | 0.33 |
| down_No. 2 | 0.350 | 3.33 | 1.17 | 415.35 | — | 0.36 | 3.33 | 1.17 | 559.64 | 0.48 | 0.35 |
| down_No. 3 | 0.350 | 3.32 | 1.16 | 411.89 | — | 0.35 | 3.33 | 1.16 | 553.93 | 0.48 | 0.34 |
| down_No. 4 | 0.350 | 3.33 | 1.16 | 388.52 | — | 0.33 | 3.33 | 1.17 | 526.87 | 0.45 | 0.36 |
| down_No. 5 | 0.350 | 3.32 | 1.16 | 406.76 | — | 0.35 | 3.33 | 1.17 | 558.07 | 0.48 | 0.37 |
| down_No. 6 | 0.350 | 3.33 | 1.16 | 408.40 | — | 0.35 | 3.33 | 1.17 | 555.45 | 0.48 | 0.36 |
| down_No. 7 | 0.350 | 3.33 | 1.17 | 410.09 | — | 0.35 | 3.52 | 1.23 | 547.35 | 0.44 | 0.33 |
| down_No. 8 | 0.350 | 3.33 | 1.16 | 413.06 | — | 0.35 | 3.33 | 1.17 | 559.04 | 0.48 | 0.35 |
| down_No. 9 | 0.350 | 3.33 | 1.16 | 422.03 | — | 0.36 | 3.33 | 1.16 | 561.07 | 0.48 | 0.33 |
| upside_No. 1 | 0.350 | 3.32 | 1.16 | 400.91 | — | 0.34 | 3.31 | 1.16 | 477.01 | 0.41 | 0.19 |
| upside_No. 2 | 0.350 | 3.38 | 1.18 | 391.92 | — | 0.33 | 3.39 | 1.19 | 470.33 | 0.40 | 0.20 |
| upside_No. 3 | 0.350 | 3.32 | 1.16 | 405.64 | — | 0.35 | 3.32 | 1.16 | 491.15 | 0.42 | 0.21 |
| upside_No. 4 | 0.350 | 3.33 | 1.17 | 416.69 | — | 0.36 | 3.34 | 1.17 | 490.17 | 0.42 | 0.18 |
| upside_No. 5 | 0.350 | 3.33 | 1.16 | 413.64 | — | 0.36 | 3.33 | 1.16 | 492.30 | 0.42 | 0.19 |
| upside_No. 6 | 0.350 | 3.32 | 1.16 | 396.21 | — | 0.34 | 3.30 | 1.16 | 460.91 | 0.40 | 0.16 |
| upside_No. 7 | 0.350 | 3.32 | 1.16 | 405.32 | — | 0.35 | 3.31 | 1.16 | 465.61 | 0.40 | 0.15 |
| upside_No. 8 | 0.350 | 3.32 | 1.16 | 406.98 | — | 0.35 | 3.33 | 1.17 | 466.96 | 0.40 | 0.15 |

^{a} measured before packaging
^{b} measured after packaging
WPE: wall plug efficiency

TABLE 4

| | Current | Voltage | Radiant Flux | Luminous | Watt | Enhance |
|---|---|---|---|---|---|---|
| Scans | (A) | (V) | mW | Flux lumen | (W) | % |
| molding_1 ^{a} | 0.350 | 3.22 | 393.76 | — | 1.13 | |
| molding_2 ^{a} | 0.350 | 3.23 | 417.55 | — | 1.13 | |
| molding_3 ^{a} | 0.350 | 3.23 | 410.18 | — | 1.13 | |
| molding_4 ^{a} | 0.350 | — | 395.41 | — | | |
| molding_5 ^{a} | 0.350 | — | 395.73 | — | | |
| molding_1 ^{b} | 0.350 | 3.23 | 557.24 | — | 1.13 | 0.42 |
| molding_2 ^{b} | 0.350 | 3.23 | 579.59 | — | 1.13 | 0.39 |
| molding_3 ^{b} | 0.350 | 3.23 | 563.80 | — | 1.13 | 0.37 |
| molding_4 ^{b} | 0.350 | — | 534.08 | — | | 0.35 |
| molding_5 ^{b} | 0.350 | — | 537.93 | — | | 0.36 |

^{a} measured before packaging
^{b} measured after packaging

What is claimed is:

1. A packaging method for semiconductor light-emitting devices, comprising the steps of:
dispensing a sealing material to encapsulate one or more semiconductor light-emitting devices disposed on a supporting mechanism;
performing a first reversing step to turn the supporting mechanism upside down; and
curing the sealing material.

2. The method as recited in claim 1, wherein said step of first reversing allows the sealing material to form a pendant shape profile by gravity.

3. The method as recited in claim 1, wherein said step of curing the sealing material is stepwise curing.

4. The method as recited in claim 3, wherein said step of stepwise curing comprises at least two steps as follows:
performing a first curing step, resulting in the sealing material reaching a tack-free state that will not deform by gravity;
performing a second curing step, further curing the sealing material reaching the tack-free state to a completely hardened or cross-linked state.

5. The method as recited in claim 4, said first curing step and said second curing step are independently selected from the group consisting of: heat-based curing, radiation-based curing, and electromagnetic wave-based curing.

6. The method as recited in claim 4, said first curing step is a heat-based curing step with a first temperature, said second curing step is a heat-based curing step with a second temperature.

7. The method as recited in claim 6, prior to said second curing step, said packaging method further comprising a second reversing step to turn the supporting mechanism back upright again.

8. The method as recited in claim 6, wherein the sealing material has a temperature-versus-storage modulus curve, which has a minimum storage modulus corresponding to a third temperature, and the first temperature is less than the third temperature.

9. The method as recited in claim 6, further comprising electrically connecting the one or more semiconductor light-emitting devices and the supporting mechanism before said second curing step.

10. The method as recited in claim 1, wherein the supporting mechanism comprises a leadframe, a sub-mount, a board, or a substrate.

11. The method as recited in claim 1, wherein, in said step of dispensing a sealing material, area covered by the sealing material on the supporting mechanism is restricted by at least one enclosed groove or at least one enclosed flange.

12. A lens with a pendant shape profile used to encapsulate one or more semiconductor light-emitting devices and enhance the output power of the one or more semiconductor light-emitting devices.

13. The lens as recited in claim 12, wherein the pendant shape profile is formed by at least partially curing lens material used to form the lens upside down, so that gravity pulls the lens material into the pendant shape profile.

14. The lens as recited in claim 12, wherein the pendant shape profile has at least two inflection points.

15. The lens as recited in claim 12, wherein the output power of the one or more semiconductor light-emitting devices is increased by 30% or more after being encapsulated by the lens.

16. The lens as recited in claim 12, further comprising one or more of the following: one or more types of phosphor, dispersing particles, and heat-dissipating particles.

17. A light-emitting device package, comprising:
a supporting mechanism for supporting one or more semiconductor light-emitting devices; and
a lens with a pendant shape profile covering the one or more semiconductor light-emitting devices.

18. The light-emitting device package as recited in claim 17, wherein the pendant shape profile is formed by at least partially curing lens material used to form the lens upside down, so that gravity pulls the lens material into the pendant shape profile.

19. The light-emitting device package as recited in claim 17, wherein the pendant shape profile has at least two inflection points.

20. The light-emitting device package as recited in claim 17, wherein the output power of the one or more semiconductor light-emitting devices is increased by 30% or more after encapsulated by the lens.

21. The light-emitting device package as recited in claim 17, further comprising one or more of the following: one or more types of phosphor, dispersing particles, and heat-dissipating particles.

22. The light-emitting device package as recited in claim 17, wherein the supporting mechanism comprises at least one enclosed groove or at least one enclosed flange, so as to restrict the area covered by the sealing material on the supporting mechanism.
